(19) United States
(12) Patent Application Publication
(10) Pub. No.: US 2013/0010444 A1
(43) Pub. Date: Jan. 10, 2013

(54) CHIP PACKAGE

(75) Inventor: KAI-WEN WU, Tu-Cheng (TW)

(73) Assignee: HON HAI PRECISION INDUSTRY CO., LTD., Tu-Cheng (TW)

(21) Appl. No.: 13/220,715

(22) Filed: Aug. 30, 2011

(30) Foreign Application Priority Data
Jul. 5, 2011 (TW) 100123745

(51) Int. Cl. H05K 1/18

(52) U.S. Cl. 361/764

(57) ABSTRACT

A chip package includes a circuit board, a chip, and wires. The circuit board includes a metal layer, a middle layer formed on the metal layer, and a wire pattern layer formed on the middle layer. The metal layer is configured to be grounded. A through hole is defined through the wire pattern layer and the middle layer to expose the metal layer. The chip is mounted on the metal layer and received in the through hole. The wires interconnect the chip and the wire pattern layer.

### BACKGROUND

1. Technical Field

The present disclosure relates to a chip package.

2. Description of Related Art

Generally, a chip package includes a number of wires to interconnect electronic components in the chip package. The wires, such as gold wires or copper wires may be attached to the chip package using wire bonding. In the chip, the wires may act as inductors and adversely affect circuit characteristics of the chip package and an electronic device having the chip package and cause circuit impedance that is hard to adapt to and increase signal loss of the chip package.

Therefore, a chip package, which can overcome the limitations described, is needed.

### BRIEF DESCRIPTION OF THE DRAWINGS

FIG. 1 is a sectional view of a chip package including a cover glass and adhesive, according to a first embodiment.

FIG. 2 is a top view of the chip package of FIG. 1, without the cover glass and the adhesive.

FIG. 3 is a sectional view of a chip package, according to a second embodiment.

### DETAILED DESCRIPTION

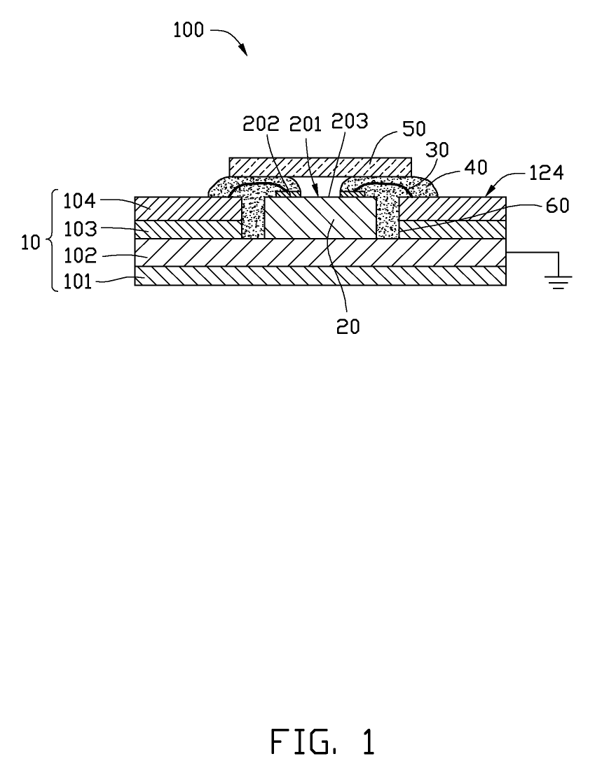

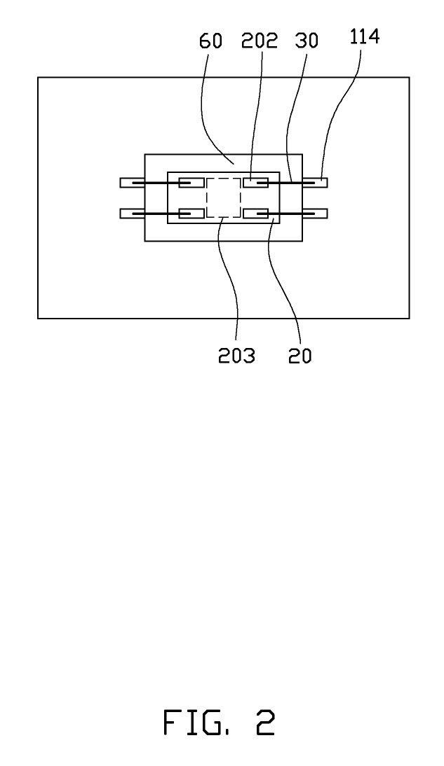

Referring to FIGS. 1-2, a chip package 100, according to a first embodiment, includes a circuit board 10, a chip 20, a number of wires 30, a protective layer 40, and a cover glass 50.

The circuit board 10 includes a base 101, a metal layer 102, a middle layer 103, and a wire pattern layer 104. The metal layer 102 is formed on the base 101. The middle layer 103 is formed on the metal layer 102. The wire pattern layer 104 is formed on the middle layer 103. The middle layer 103 may be a single insulating layer or a multi-layer structure including a metal layer and an insulating layer that are stacked in an alternate fashion.

In this embodiment, the base 101 is ceramic. The metal layer 102 is grounded. Referring to FIG. 2, the wire pattern layer 104 includes four connection pads 114.

A through hole 60 is defined through the wire pattern layer 104 and the middle layer 103 to expose the metal layer 102. The chip 20 is mounted on the metal layer 102 and received in the through hole 60. The grounded metal layer 102 can enhance heat dissipation of the chip 20 and shield against electromagnetic interference between other electronic components and the chip 20. The other electronic components may be electronic components of the chip package 100 and/or of an electronic device where the chip package 100 is installed. The chip 20 may be adhered to the metal layer 102 by an insulating adhesive.

The wires 30 interconnect the chip 20 and the wire pattern layer 104. In detail, the chip 20 includes a first top surface 201 and four chip pads 202 formed on the first top surface 201. The wire pattern layer 104 includes a second top surface 124. In this embodiment, the first top surface 201 and the second top surface 124 are at the same level. The number of the wires 30 is four. Each wire 30 interconnects a chip pad 202 and a corresponding connection pad 114. The wires 30 may be formed by a wire bonding method. The wires 30 may be made of gold, copper, aluminum, or any alloy thereof. In alternative embodiments, the first top surface 201 is higher or lower than the second top surface 124.

Material of the protective layer 40 may be heat-curable, such as polyimide resin, epoxy resin, silicone resin or the like. The protective layer 40 covers the wires 30, and joint portions between the wires 30 and the chip pads 202 and joint portions between the wires 30 and the connection pads 114. The protective layer 40 also fills in the through hole 60. The protective layer 40 can strengthen connections between the wires 30 and the chip pads 202, and between the wires 30 and the connection pads 114 and enhance anti-oxidation ability of the wires 30, the chip pads 202, and the connection pads 114 to prolong the lifetime of the chip package 100. In this embodiment, the first top surface 201 includes an exposed region 203. The exposed region 203 is free of the protective layer 40 thereon and faces the cover glass 50. When the chip 20 is a laser diode or a photo diode, the exposed region 203 corresponds to a light emitting region of the laser diode or a light receiving portion of the photo diode.

The cover glass 50 is attached to the protective layer 40 to cooperatively seal the chip 20 to prevent penetration by dust and water vapor.

In the chip package 100, since the chip 20 is received in the through hole 60, a height difference between the chip pad 202 and the connection pad 114 is reduced. Therefore, the wire 30 interconnecting the chip pad 202 and the connection pad 114 is shortened to minimize any inductive effect of the wire 30 and to reduce the amount of material needed for the wire 30.

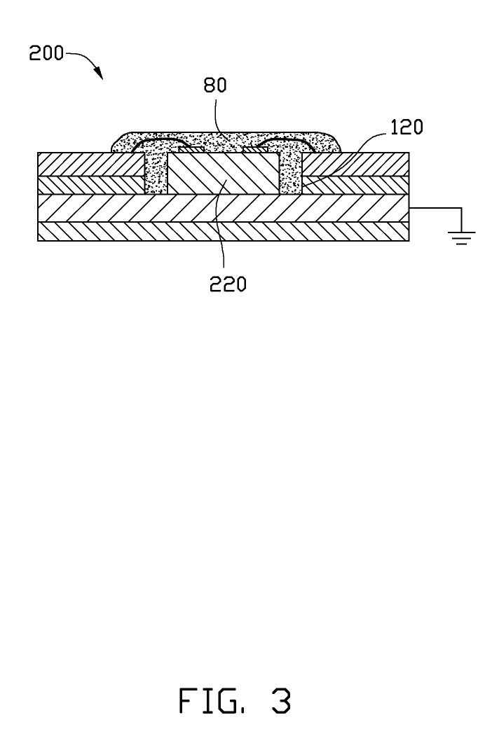

Referring to FIG. 3, a chip package 200, according to a second embodiment, is shown. The difference between the chip package 200 and the chip package 100 is that a cover glass is omitted and a protective layer 80 fills in a through hole 120 and entirely covers a chip 220.

Although numerous characteristics and advantages of the present embodiments have been set forth in the foregoing description, together with details of the structures and functions of the embodiments, the disclosure is illustrative only, and changes may be made in detail, especially in matters of shape, size, and the arrangement of parts within the principles of the disclosure to the full extent indicated by the broad general meaning of the terms in which the appended claims are expressed.

What is claimed is:

1. A chip package comprising:
a circuit board comprising a metal layer, a middle layer formed on the metal layer and a wire pattern layer formed on the middle layer, the metal layer configured to be grounded, a through hole defined through the wire pattern layer and the middle layer to expose the metal layer;
a chip mounted on the metal layer and received in the through hole; and
a plurality of wires interconnecting the chip and the wire pattern layer.

2. The chip package of claim 1, wherein the chip comprises a first top surface and a plurality of chip pads formed on the first top surface, the wire pattern layer comprises a second top surface and a plurality of connection pads, each wire interconnects a chip pad and a corresponding connection pad.

3. The chip package of claim 2, wherein the first top surface and the second top surface are at the same level.

4. The chip package of claim 2, further comprising a protective layer covering the wires, joint portions between the wires and the chip pads and joint portions between the wires and the connection chips.

5. The chip package of claim 4, wherein a material of the protective layer is a heat-curable material.

6. The chip package of claim 4, further comprising a cover glass attached to the protective layer, the cover glass and the protective layer cooperatively sealing the chip.

7. The chip package of claim 6, wherein the first top surface comprises an exposed region free of the protective layer thereon, the exposed portion facing the cover glass.

8. The chip package of claim 4, wherein the protective layer fills in the through hole and entirely covers the chip.

9. The chip package of claim 1, wherein the chip is insulated from the metal layer.
